(19) United States
(12) Patent Application Publication
(10) Pub. No.: US 2024/0345664 A1
(43) Pub. Date: Oct. 17, 2024

(54) Through Hole Keyboard

(71) Applicant: Microsoft Technology Licensing, LLC, Redmond, WA (US)

(72) Inventors: Masaaki FUKUMOTO, Shenzhen (CN); Paul Christopher KOS, Shenzhen (CN); Kelong ZHAO, Shenzhen (CN); Haiji SUN, Shenzhen (CN); Bin ZHAI, Shenzhen (CN); Mingjie WANG, Shenzhen (CN)

(73) Assignee: Microsoft Technology Licensing, LLC, Redmond, WA (US)

(21) Appl. No.: 18/683,759

(22) PCT Filed: Sep. 3, 2021
(86) PCT No.: PCT/CN2021/116408

§ 371 Date: Feb. 14, 2024

(51) Int. Cl. G06F 3/02; H01H 13/70; H01H 13/704; H01H 13/7065; H01H 13/81

(52) U.S. Cl. CPC G06F 3/0224; H01H 13/7006; H01H 13/704; H01H 13/7065; H01H 13/81; H01H 2225/028

(57) ABSTRACT

The present description relates to devices, such as keyboards. One example can include a top portion and an opposing bottom portion and key switches that are mechanically retained in holes formed in the top cover. The example can also include electrical traces formed on the top cover that extend from the holes to a processing unit that is configured to receive electrical signals along the electrical traces when the key switches are closed.

### BACKGROUND

Many users tend to prefer the haptic and/or audible feedback provided by mechanical keyboards (e.g., a keyboard employing mechanical keys). Mechanical keyboards tend to be constructed from the base up. Printed circuit boards (PCBs) are positioned on the base and keys are positioned on and engage the PCBs. Finally, a cosmetic top cover is positioned around the keys and fastened to the base to create a finished look and to reduce the chance of contaminants entering the keyboard.

### SUMMARY

This patent relates to devices, such as keyboards. One example can include a top portion and an opposing bottom portion and key switches that are mechanically retained in holes formed in the top cover. The example can also include electrical traces formed on the top cover that extend from the holes to a processing unit that is configured to receive electrical signals along the electrical traces when the key switches are closed.

This Summary is intended to aid the reader as an introduction to some of the present concepts and is not intended to be limiting.

### BRIEF DESCRIPTION OF THE DRAWINGS

The accompanying drawings illustrate implementations of the concepts conveyed in the present document. Features of the illustrated implementations can be more readily understood by reference to the following description taken in conjunction with the accompanying drawings. Like reference numbers in the various drawings are used wherever feasible to indicate like elements. Further, the left-most numeral of each reference number conveys the FIG. and associated discussion where the reference number is first introduced. Where space permits, elements and their associated reference numbers are both shown on the drawing page for the reader's convenience. Otherwise, only the reference numbers are shown.

FIGS. 1A, 2C-2E, 4B, and 5B show perspective views of example devices in accordance with some implementations of the present concepts.

FIGS. 1B, 1C, 2A, 3, 5A, 7A, 7C, and 8 show exploded perspective views of example devices in accordance with some implementations of the present concepts.

FIGS. 2B, 4A, 5C-5F, 6, and 7B show elevational views of example devices in accordance with some implementations of the present concepts.

### DESCRIPTION

The present concepts relate to devices, such as keyboards that include keys to facilitate user input. Traditionally, the keys were supported by, and electrically connected to, underlying electronic components, such as printed circuit boards positioned on a bottom portion. Thus, key function (e.g., registering a user activation of a key) involved both the key and the underlying electronic components of the bottom portion. In this configuration, the overall shape of the keys, whether planar or ergonomic, has to be approximated by the underlying electronic components of the bottom portion. This configuration was relatively economically expensive and had a relatively large ecological cost (e.g., large carbon footprint). A superficial top portion or top cover was paired with the bottom portion to provide a ‘finished appearance’ to the keyboard and to cover gaps around the keys and support the user's hands. However, gaps between the top cover and the keys and/or between individual keys still provided pathways for foreign objects to enter the keyboard.

In contrast, the present concepts can form through holes in a top portion. Key switches can be positioned in these through holes to reduce and/or eliminate pathways for contamination to enter the keyboard. Further, the key switches can be electrically connected to the top portion. The top portion can include electrical traces from the key switches to a processing unit that is positioned at a convenient location on the top portion. Thus, the key switches can function to register user selections without any underlying electronic components on the bottom or base portion. Instead, the bottom portion can simply be manifest as a base that physically supports the top portion. Associating the key switches and the electronic traces with the top portion provides a technical solution of eliminating the need to approximate the overall keyboard configuration (e.g., planar or curved) on the underlying electronics of the bottom portion. These and other aspects are described in more detail below.

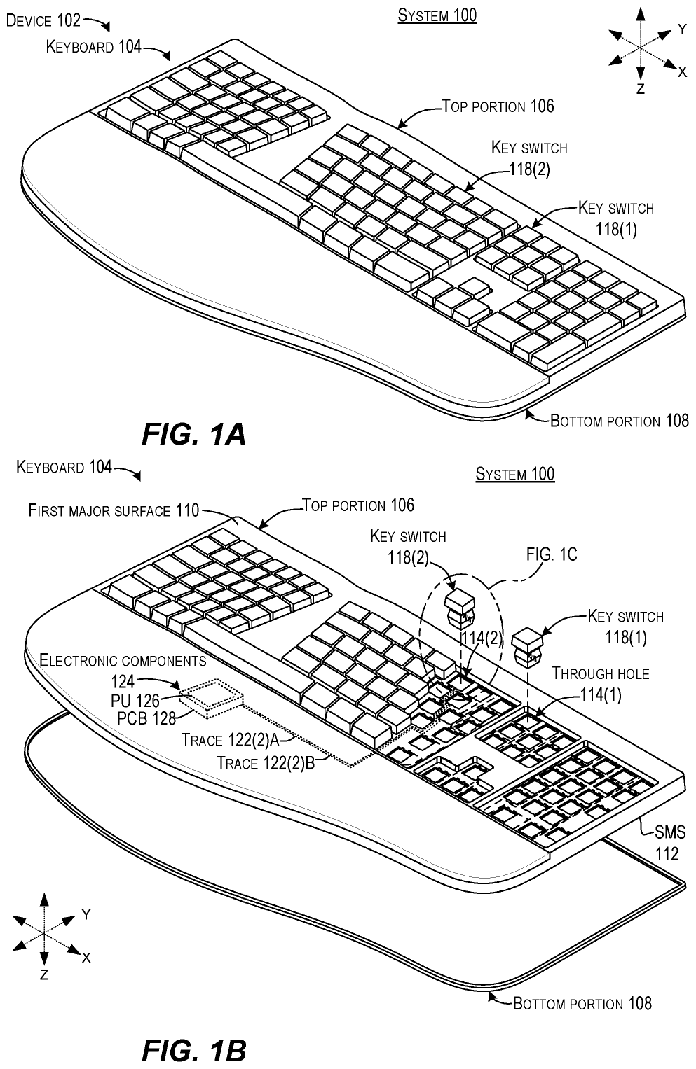

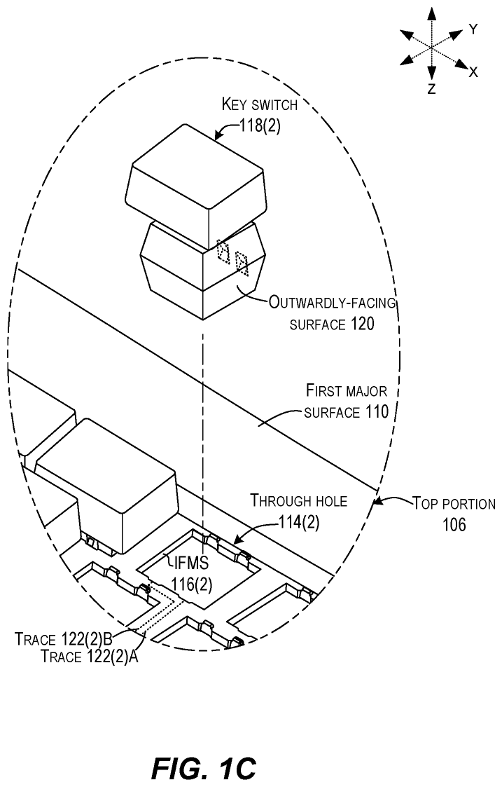

Introductory FIGS. 1A-1C collectively show an example system 100 that includes a device 102. In this case, the device 102 is manifest as a keyboard 104. In this example, the keyboard 104 is represented as a full keyboard (e.g., “QWERTY” or “DVORAK”), but the term keyboard 104 as used herein is intended to cover any type of keyboard, keypad and/or user input device that includes user-selectable keys.

The keyboard 104 can include a top portion 106 and a bottom portion 108. The top portion 106 can define first and second major surfaces 110 and 112. Through holes 114 can extend between first major surface (FMS) 110 and second major surface (SMS) 112. The through holes 114 can be defined by inwardly-facing minor surfaces (IFMS) 116 (FIG. 1C). Note that to avoid clutter on the drawing pages only some instances of the elements are designated.

Key switches 118 can be positioned in the through holes 114. The key switches 118 can have outwardly-facing surfaces (OFS) 120 (FIG. 1C) that can approximate a shape and/or size of the through holes 114. The key switches 118 can be electrically coupled at the through holes 114 to electrical or conductive traces (hereinafter, “traces”) 122 positioned on the top portion 106. The traces 122 can extend from the key switches 118 to electronic components 124, such as processing unit 126. To avoid clutter on the drawing page, only traces 122(2)A and 122(2)B relating to key switch 118(2) are shown on FIGS. 1B and 1C. The traces 122 and the electronic components 124 are shown in ghost because they could be positioned on second major surface 112 and thus would be obstructed in these views. The electronic components 124, such as the processing unit 126 can be positioned on a printed circuit board (PCB) 128 or formed directly on the top portion 106. In either case, the electronic components 124, such as the PCB 128 do not need to be positioned under the key switches 118. Instead, the present implementations offer the technical benefit of allowing electronic components 124, such as the PCB 128 to be positioned at convenient locations where space permits, rather than having to underly the key switches.

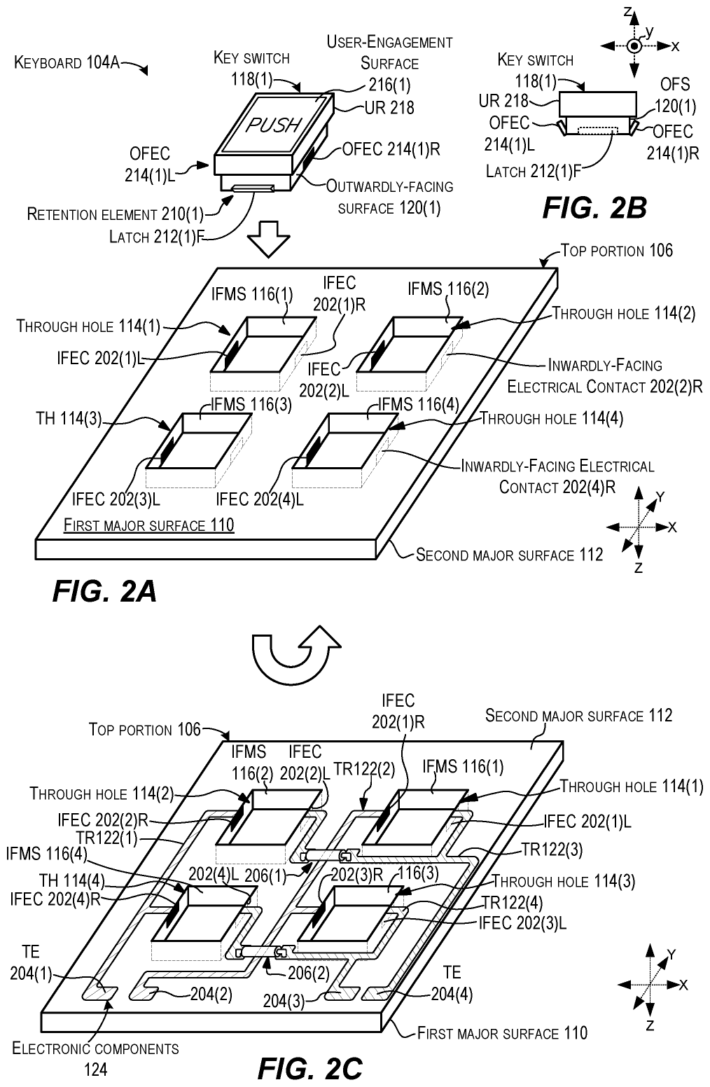

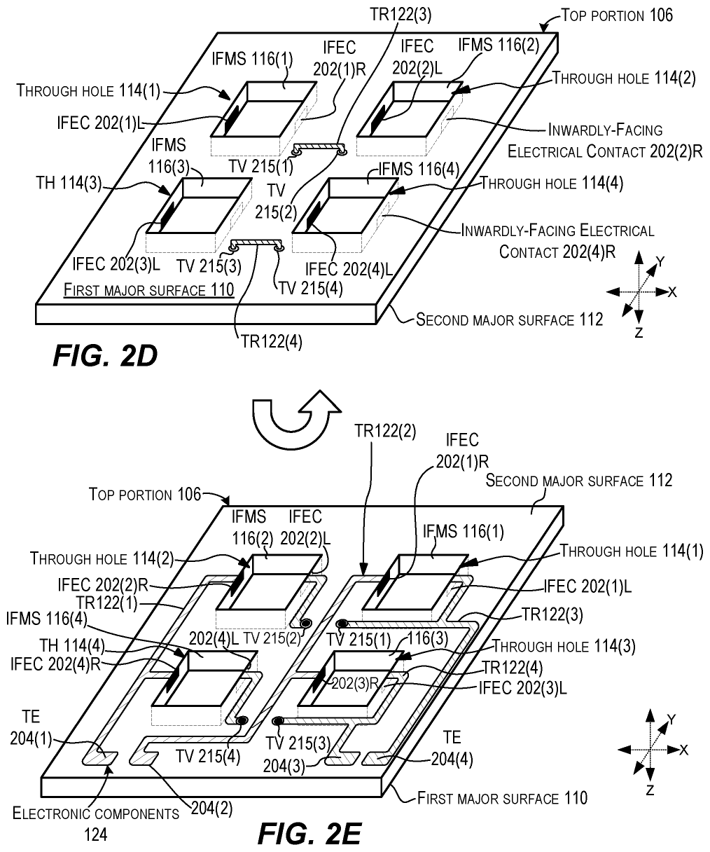

FIGS. 2A-2E collectively show another example keyboard 104A that includes keyboard top portion 106. The use of the suffix, such as “A” relative to keyboard 104A is intended to convey that some components of keyboard 104A may be different from those of keyboard 104 described above and/or those keyboards described below having a different suffix. FIG. 2A is a perspective view from above the keyboard and FIG. 2C is a corresponding perspective view from below the keyboard. FIG. 2B is an elevational view of the keyboard's key switch 118(1) shown in FIG. 2A. FIGS. 2D and 2E are similar to views 2A and 20, respectively, and show keyboard variations.

In this example the keyboard top portion 106 shows four through holes 114. Each through hole 114 can receive a key switch 118. Note however, to avoid clutter on the drawing page, only one key switch 118(1) is shown. The description relating to the illustrated implementation is also applicable to other keyboard implementations. For instance, keyboard 104A can represent a portion of a larger keyboard that contains more than four keys, such as keyboard 104 of FIGS. 1A-1C.

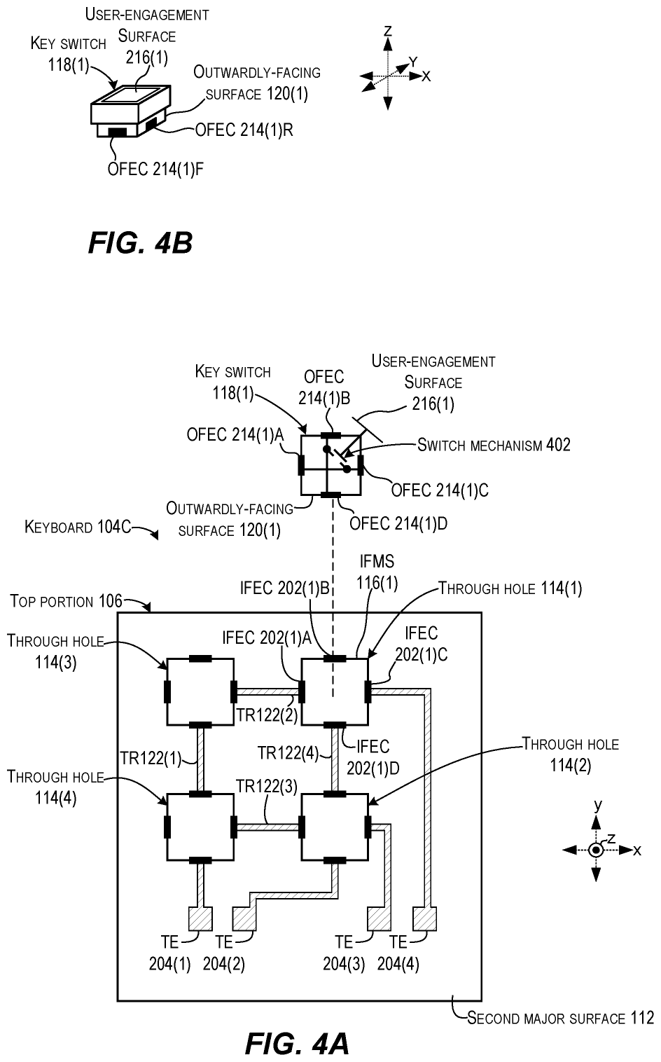

In this case, inwardly-facing electrical contacts 202 can be positioned on the inwardly-facing minor surfaces 116. In this example, two generally opposing inwardly-facing electrical contacts 202 are positioned relative to each through hole 114 and are distinguished with the suffixes “L” for left and “R” for right. Implementations with more inwardly-facing electrical contacts 202 are described below relative to FIGS. 4A-8.

Traces 122 can be positioned on the top portion 106. In this case, the traces 122 are positioned directly on the second major surface 112 as illustrated in FIG. 2B. In the illustrated configuration, the traces 122 extend from the inwardly-facing electrical contacts 202 to terminal electrodes 204. The terminal electrodes 204 can in turn be electrically coupled to various electronic components 124(FIG. 1B). Alternatively, and as shown relative to FIG. 1B, the traces can extend all the way to the electronic components. Trace 122(1) extends between inwardly-facing electrical contacts 202(2)R and 202(4)R and terminal electrode 204(1). Trace 122(2) extends between inwardly-facing electrical contacts 202(1)R and 202(3)R and terminal electrode 204(2). Trace 122(3) extends between inwardly-facing electrical contacts 202(4)L and 202(3)L and terminal electrode 204(3). Trace 122(4) extends between inwardly-facing electrical contacts 202(2)L and 202(1)L and terminal electrode 204(4).

Jumper wires 206 can be utilized to isolate (e.g., insulate) traces 122 from one another. For instance, jumper wire 206(1) can isolate trace 122(2) from trace 122(3) where they cross paths. Similarly, jumper wire 206(2) can isolate trace 122(2) from trace 122(4) where they cross paths.

Key switches 118 can define outwardly-facing surfaces 120. The outwardly-facing surfaces 120 can have a shape that approximates (e.g., engages) the inwardly-facing minor surfaces 116 of the through hole so that the key switch fits in and is retained in the top portion 106. In this case, the inwardly-facing minor surfaces 116 approximate a rectangular shape and the outwardly-facing surfaces 120 approximate a similar (and potentially very slightly smaller) rectangular shape. Other shapes, such as square and/or circular are contemplated.

In this implementation, the key switches 118 include retention elements 210. In this case, the retention elements 210 are manifest as latches 212 that extend outwardly (in the x and/or y reference directions) from the key switch 118. When the key switch 118 is installed in the through hole 114 with downward pressure in the z reference direction, the latches 212 can pass through the through hole 114 and then engage the second major surface 112 to retain the key switch 118 in the top portion 106 so the key switch will not accidentally or inadvertently come out.

Installation of the key switch 118 in the through hole 114 can automatically cause the key switch to be physically secured relative to the top portion 106 (e.g., the key switch does not move relative to the top portion on its own). In some configurations, the key switch 118 can be removed from the top portion 106 by applying sufficient upward force to the key switch to overcome the retention element 210. Thus, the key switch 118 can be readily replaced if it fails or for other reasons described below.

Key switches 118 can include outwardly-facing electrical contacts 214 on the outwardly-facing surfaces 120. When the key switch 118 is installed in the through hole 114, the outwardly-facing electrical contacts 214 can be automatically aligned with, and electrically-engage, the inwardly-facing electrical contacts 202. This automatic alignment can be facilitated because the outwardly-facing electrical contacts 214 can be positioned on, and located by the outwardly-facing surfaces 120. Recall that as mentioned above the outwardly-facing surfaces 120 can approximate the shape and size of the inwardly-facing minor surfaces 116 on which the inwardly-facing electrical contacts 202 are positioned. Accordingly, the present implementations can provide a technical solution of auto-aligning and electrically coupling the outwardly-facing electrical contacts 214 and the inwardly-facing electrical contacts 202 when the key switch 118 is inserted into the through hole 114. Further, this technical solution can be achieved without soldering or other affirmative processes to electrically connect the key switch 118 to the traces 122.

The installation of the key switch 118 in the through hole 114 can automatically electrically connect the key switch to various electronic components via the traces 122. When key switch 118 is inserted into the through hole 114 from the top side (e.g., the first major surface 110), the key switch's outwardly-facing electrical contacts 214 contact the top portion's inwardly-facing electrical contacts 202. As shown in FIG. 2B, in some implementations the key switch's outwardly-facing electrical contacts 214 can have a spring contact function (e.g., phosphor bronze plate) for secure contact. At this point in the assembled configuration, the key switch 118 can function as a switch in the open position (e.g., electrical path through the key is discontinuous).

To select a key (e.g., user input of a letter, number, symbol, character, etc.), the user can push down on a user-engagement surface 216 of the key switch 118. In some implementations, the user-engagement surface 216 can be generally parallel to the first major surface, such as +/−20 degrees, for instance. The user-engagement surface 216 can be forced downward (e.g., downward movement) relative to the remainder of the key switch 118 until the key switch transitions to a closed position and completes an electrical path through the key switch. For instance, key activation can be achieved by depressing user-engagement surface 216(1) of key switch 118(1) perpendicular to the first major surface 110 until the switch closes and completes an electrical circuit from terminal electrode 204(4), through trace 122(3), inwardly-facing electrical contact 202(1)L, outwardly-facing electrical contact 214(1)L, outwardly-facing electrical contact 214(1)R, inwardly-facing electrical contact 202(1)R, trace 122(2), and terminal electrode 204(2). When the user releases the user-engagement surface 216, the key switch 118(1) returns to the open position.

Note that in this implementation, the user-engagement surface 216(1) can move within the key switch 118(1) and the outwardly-facing surface 120 does not need to move relative to the top portion 106. Instead, the key switch 118 can be friction fit in the top portion 106, which can reduce and potentially eliminate contaminants passing between the key switch and top portion. In the illustrated configuration, an upper region 218 of the key switch can be larger than the through hole 114 and rest against the first major surface 110 to further block contaminant entry. Thus, the present implementations can provide a technical solution of sealing the key switches 118 to the top portion 104 to eliminate gaps for contaminant entry associated with traditional designs.

In this implementation, the top portion 106 can be viewed as a keypad plate that has through holes 114 formed through it. The key switches 118 can function as self-contained switches that are suspended from the top portion 106. The key switches 118 do not engage any underlying electronics, such as PCBs. Instead, the key switches 118 are suspended from the top portion 106 and electrically coupled to electronic components via the electronic traces 122 of the top portion. The keyboard shape is defined by the top portion 106 (e.g., planar, curved, ergonomic, etc.). The key switches 118 are suspended from the top portion 106 and naturally follow along the shape of the top portion. The top portion 106 can have any shape such as planer, ergonomic, ball, and also any other 2-dimensional/3-dimensional curved shapes and their combinations.

The key switches 118 can function as self-contained electrical switches without any underlying electronic components. Thus, these implementations provide a technical solution of defining a shape of the keyboard with the top portion, supporting the key switches with the top portion, and electrically connecting the key switches to other electronic components with traces formed on the top portion instead of relying on underlying (e.g., positioned on the bottom portion) electronic components that have to mechanically and electrically contribute to the key function.

In some implementations, the top portion 106 can be made of dielectric materials (e.g., plastics, glass), however, conductive materials (e.g., metals) can also be used by covering/painting/coating with dielectric materials. Various techniques can be employed for making traces 122 on the top portion 106. Example techniques can include embedding conductive plates/wires, pasting conductive tape, conductive painting/plating, and/or photoetching, among others. Other example techniques can include “Molded Interconnect Device (MID)”, “Laser Direct Structuring (LDS)”, and/or “Selective Surface Activation Induced by a Laser (SSAIL),” among others.

When traces 122 are employed in a single layer, jumper wire(s) 206 can be used for making a switch matrix. Conductive tape, wire bonding, and/or SMD soldering techniques, among others, can also be employed. If conductive traces are employed in a multi-layer capability, no extra jumpers are employed. In some implementations electronic components 124, such as additional electric parts (e.g., resisters, capacitors, LEDs, diodes, transistors, and/or even microcontrollers) can be directly soldered onto the conductive traces at a convenient location on the top portion (e.g., not directly underlying the key switches).

FIGS. 2D and 2E show another example top portion 106 configuration that offers an alternative to employing jumper wires where traces 122 would intersect. In this case, trace 122(3) is extending horizontally between through hole 114(2) and through hole 114(1). Similarly, trace 122(4) is extending horizontally between through hole 114(4) and through hole 114(3). Trace 122(2) is extending generally vertically through this region. To avoid a short circuit and avoid the use of jumper wires, ‘through vias’ 215 are employed. Traces 122(3) and 122(4) (or other conductor) are extended through the ‘through vias’ 215 to the first major surface 110 to avoid intersection with trace 122(2). For instance, trace 122(3) travels through ‘through via’ 215(1) from the second major surface 112 to the first major surface 110 on one side of trace 122(2) and returns to the second major surface 112 on the other side of trace 122(2) through ‘through via’ 215(2). Similarly, trace 122(4) travels through ‘through via’ 215(3) from the second major surface 112 to the first major surface 110 on one side of trace 122(2) and returns to the second major surface 112 on the other side of trace 122(2) through ‘through via’ 215(4). In such implementations, another layer may be positioned over the first major surface 110 to protect the traces 122(3) and 122(4). For instance, the traces on the first major surface 110 and/or the ‘through vias’ 215 can be painted/coated for realizing waterproof and/or scratchproof functions.

In the illustrated 2×2 keyboard 104A configurations of FIGS. 2A-2E, the key switches 118 can be connected to processing unit (126, FIG. 1B) with terminal electrode(s) 204 by directly soldering wires/connectors, card-edge connectors, and/or also anisotropic conductive adhesives/films/connectors, among other solutions.

In review, FIGS. 2A-2E collectively show a keyboard 104A that illustrates some of the present concepts. This top portion 106 can function as a 2×2 key switch matrix when four key switches 118 are installed in all four through holes 114. Alternatively or additionally, the concepts explained here can be applied to keyboards having many more key switches, which would be difficult to illustrate at a similar level of granularity as shown relative to this four key switch configuration. With the key switches 118 installed in the top portion 106, the keyboard 104A is fully functional and can be paired with a bottom portion or employed in other devices, such as in a vehicle control area, such as a car dashboard or an airplane cockpit.

Unlike traditional designs where keys are soldered to underlying PCBs, key switches 118 can be easily removed by just pulling from the top side. This removability can enable easy repair and modification even by end-users. The retention element 210 configuration can be selected to allow or prevent key switch removal as defined in a particular set of design specifications. In the case of removable key switches, the retention element 210 can be designed so that a specified amount of upward force overcomes the retention element and allows the key switch to be removed and replaced.

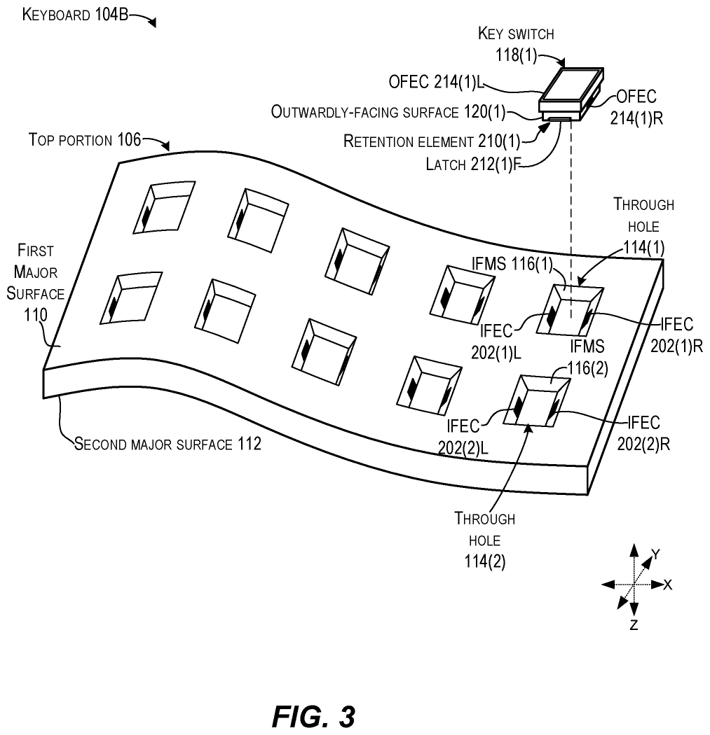

FIG. 3 shows another example keyboard 104B that is similar to keyboard 104A of FIG. 2A. As such, not all elements are re-introduced for sake of brevity. In this case, keyboard 104B includes a curved top portion 106, such as may be employed on an ergonomic keyboard. Ten through holes 114 are shown in the top portion 106 though only two are designated in order to avoid clutter on the drawing page. Key switches 118 can be installed in the through holes 114. Only one key switch 118(1) is shown on the drawing page to avoid clutter, but a key switch 118 can be provided for each through hole 114.

Key switches 118 can be positioned in through holes 114 defined in the top portion 106 without using underlying PCB/FPC. Tracing techniques (e.g., MID/LDS/SSAIL) can be employed for 3D-curved surfaces, so that any kind of curved shape (e.g., “ergonomic”) and/or special layout keyboard units can easily be made without making complicated PCB/FPC substrates that underly and contact the keys. Because the key switches can be supported by, and suspended from, the through holes 114, the key switches 118 will collectively automatically conform to the shape of the top portion 106.

FIGS. 4A and 4B collectively show another example keyboard 104C. FIG. 4A shows top portion 106 with an associated key switch 118. In this example the top portion 106 is shown with four through holes 114(1)-114(4) in a similar arrangement to top portion 106 of FIG. 2A. To avoid clutter on the drawing page only one corresponding key switch 118(1) is illustrated. FIG. 4B shows a perspective view of key switch 118(1).

FIG. 4A represents an example key switch wiring configuration. Key switch 118(1) has outwardly-facing electrical contacts 214(1) on each side. Outwardly-facing electrical contacts 214(1)A and 214(1)C are connected in the key switch 118(1) (e.g., to inwardly-facing electrical contacts 202(1)A and 202(1)C). Outwardly-facing electrical contacts 214(1)B and 214(1)D are connected to inwardly-facing electrical contacts 202(1)B and 202(1)D. The key switch's switch mechanism 402 is connected between both horizontal “A/C” wiring and the vertical “B/D” wiring. Therefore, when the user-engagement surface 216(1) of the switch is depressed, all four electrodes are connected by the closing of the switch mechanism 402. The switch mechanism can comprise a spring and plunger assembly or a scissor mechanism, among others.

In this illustrated example, keyboard 104 has four through holes 114(1)-114(4). Each through hole 114 has an inwardly-facing electrical contact 202 on each side wall (e.g., each facet of the inwardly-facing minor surfaces 116). Keyboard 104C also has a 2×2 key matrix pattern with traces 122(2) and 122(3) for row connection and with traces 122(1) and 122(4) for column connection.

When key switches 118 are inserted into all four through holes 114(1)-114(4), left/right (e.g., inwardly-facing electrical contacts 202(1)A and 202(1)C and outwardly-facing electrical contacts 214(1)A and 214(1)C) and up/down electrodes (e.g., inwardly-facing electrical contacts 202(1)B and 202(1)D and outwardly-facing electrical contacts 214(1)B and 214(1)D) are connected through key switch 118(1) for example. Therefore, no extra jumper wires are needed to the make 2×2 matrix. In review, this implementation can reduce or eliminate the use of jumper wires 206 described above relative to FIG. 2C to insulate traces 122 when they cross one another on the top portion 106. Instead of employing jumper wires or other insulative elements, the illustrated configuration offers the technical solution of allowing traces 122 to cross in the key switch 118 thereby eliminating the risk of a short circuit between intersecting traces.

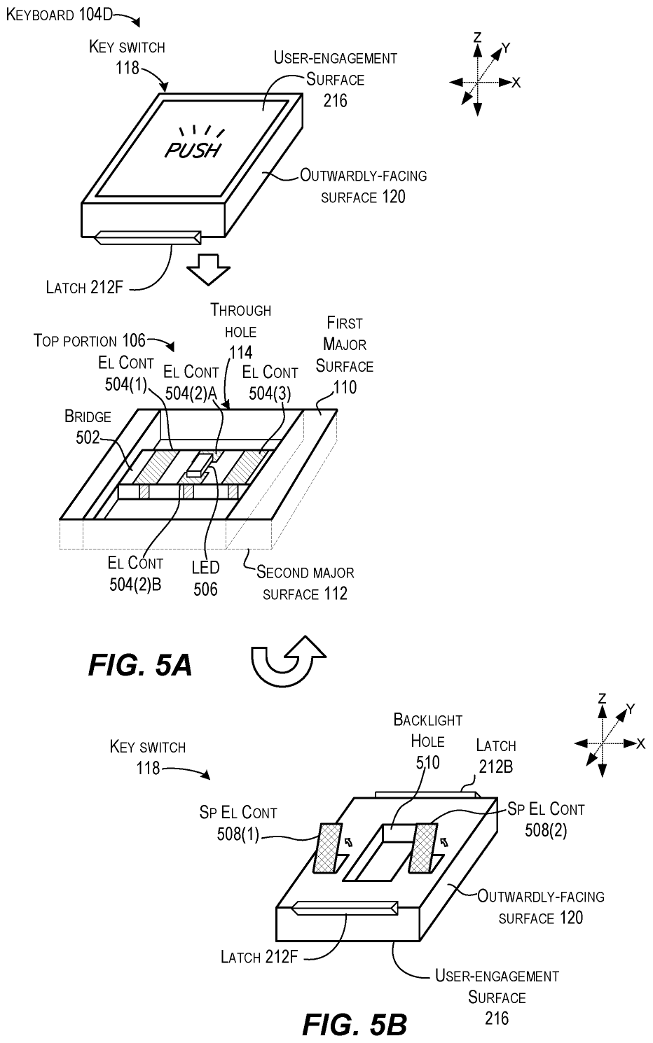

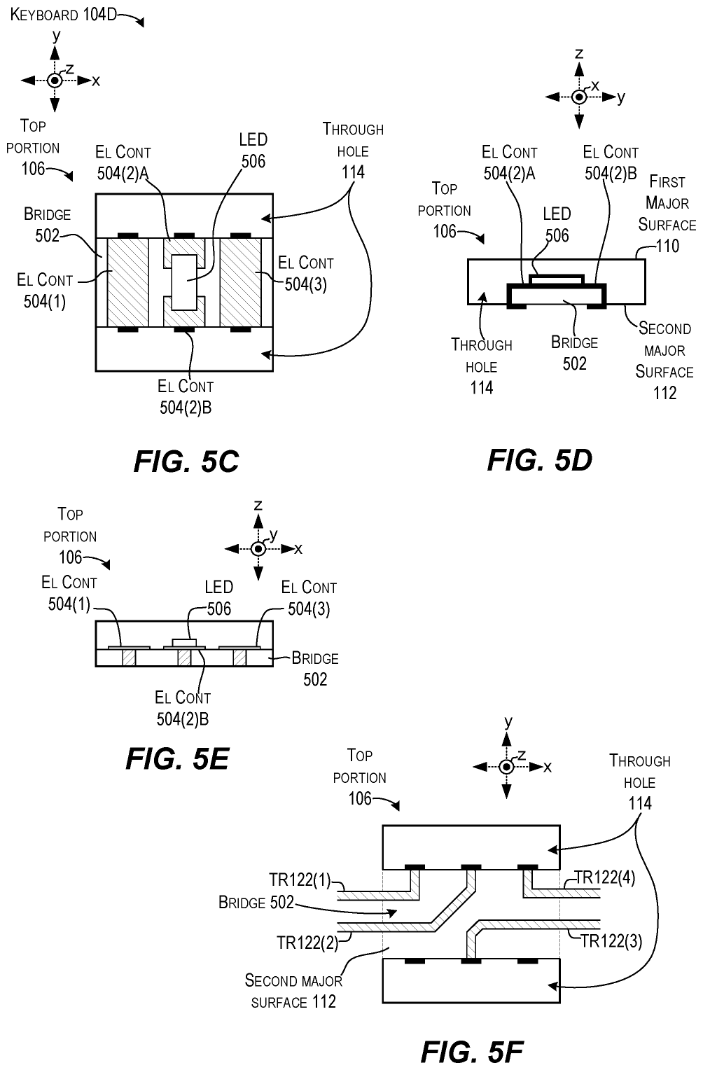

FIGS. 5A-5F collectively show another example keyboard 104D. FIG. 5A shows top portion 106 with an associated key switch 118. FIG. 5B shows the underside (e.g., opposite side) of the key switch 118. FIG. 5C shows a view from above top portion 106 centered on the through hole 114 (e.g., top view). FIG. 5D shows a side view of the through hole in the top portion. FIG. 5E shows a side view of the through hole through the top portion taken 90 degrees from the view of FIG. 5D (e.g., front view). FIG. 5F shows a view from below the top portion centered on through hole 114 taken from the opposite perspective as FIG. 5C (e.g., bottom view).

For ease of illustration, only one through hole 114 is illustrated, but the concepts are applicable to multiple through hole implementations. In this implementation, the through hole 114 includes a bridge 502 of top portion material extending from one side of the through hole to the other. Electronic components can be positioned on the bridge 502 across the through hole 114. In this example, the electronic components include electrical contacts 504, traces 122, and an LED light 506. In this configuration, electrical contacts 504(1) and 504(2) can relate to conveying key switch activation as has been described above. Electrical contacts 504(2)A and 504(2)B are electrically coupled to LED 506 and can provide electrical power to activate (e.g., light) the LED. The electrical contacts 504 can be coupled to traces 122 which can extend on the top portion to the processing unit discussed above relative to FIG. 1B.

In this configuration, the key switch 118 includes downwardly facing spring electrical contacts 508(1) and 508(2) that align with and engage electrical contacts 504(1) and 504(3), respectively. Latches 212 pass through the through hole 114 and engage the second major surface 112 to retain the key switch 118 in the through hole 114 despite upward bias created by downwardly facing spring electrical contacts 508.

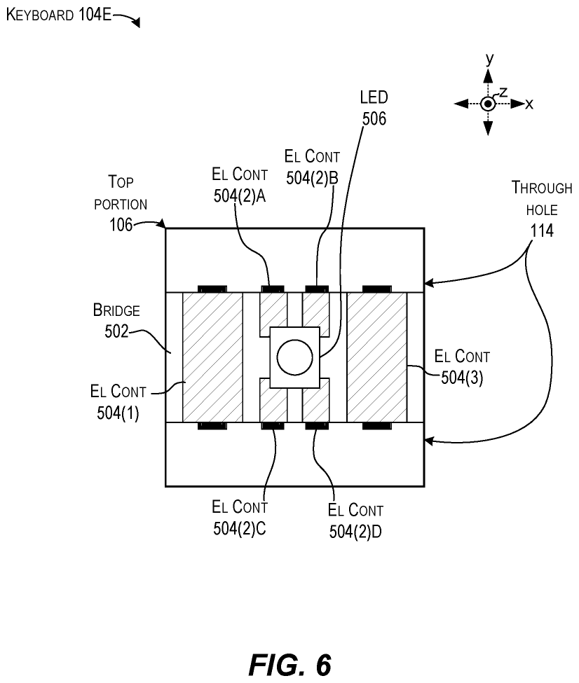

In this implementation, the key switch 118 is electrically isolated from the LED 506 and the electrical contacts 504(2). Physically, the key switch 118 includes a backlight hole 510 (e.g., a recess) that is configured to accommodate the LED 506. The user-engagement surface 216 can be transparent or semi-transparent to allow light from the LED to be emitted from the key switch 118. The illustrated configuration powers a single-color LED on the bridge 502. An example implementation for a multi-color LED is described below relative to FIG. 6.

In review, through hole 114 can include bridge 502. The bridge can include upwardly-facing electrical contacts 504. Some or all of these traces 122 can be employed for engaging key switch 118 for conveying switch input (e.g., open or closed switch state). In the illustrated configuration, electrical contacts 504(1) and 504(3) engage the key switch. Other, electrical contacts can relate to other functionality. In this case, the other functionality relates to backlighting the key switch with LED 506 that is connected across electrical contacts 504(2)A and 504(2)B. Traces 122 positioned on second major surface 112 can extend onto the bridge 502 to the electrical contacts 504. In this example, trace 122(1) is connected to electrical contact 504(1), trace 122(2) is connected to electrical contact 504(2)A, trace 122(3) is connected to electrical contact 504(2)B, and trace 122(4) is connected to electrical contact 504(3). The traces 122 can extend on the top portion 106 as described above relative to FIGS. 1A-1C, 2A-2C, and/or 4A-4B. As mentioned above, this implementation can be viewed as having self-contained key switches that are fully supported (both mechanically and electronically) by the top portion and do not rely on any underlying electronic components, such as PCBs associated with the bottom portion.

FIG. 6 shows another example keyboard 104E. FIG. 6 is similar to FIG. 5C except that in this case, four electrical contacts 504(2)A-504(2)D are provided on bridge 502 to power full color LED 506 (e.g., ground+three color elements). Other components can be similar to those described above relative to FIGS. 5A-5F and as such are not re-introduced here for sake of brevity.

In review, multicolor backlighting of individual key switches 118 can be enabled by using multi-color/full-color LEDs associated with the top portion 106. When using full-color-LEDs, a total of four electrical contacts 504(2)A-504(2)D and corresponding traces 122(1)-122(4) can be employed. Both analog-control (with conventional RGB LED) and digital-control (e.g., worldsemi 4-pin protocol: http://www.world-semi.com/solution/list-4-1.html) can be employed.

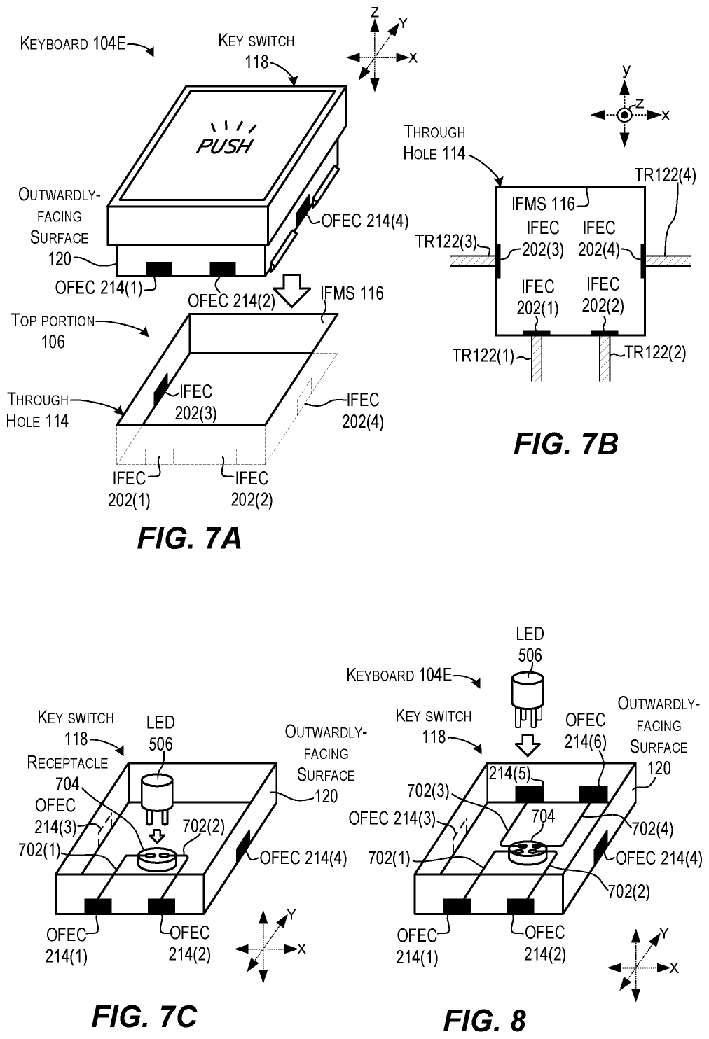

FIGS. 7A-7C show another example keyboard 104E that can employ an alternative backlight solution. In this case, as shown in FIG. 7C, the LED 506 can be contained in the key switch 118. Within the key switch 118, conductors 702 can connect the LED to outwardly-facing electrical contacts 214. The LED 506 can be connected to the conductors 702 in various ways, such as directly or via a receptacle or socket 704.

This implementation is similar to keyboard 104A described above relative to FIGS. 2A-2C in regard to the key switch 118 being coupled to the top portion 106 via outwardly-facing electrical contacts 214. In this case, outwardly-facing electrical contacts 214(1) and 214(2) are configured to couple to conductors 702(1) and 702(2) and hence the LED 506. Outwardly-facing electrical contacts 214(1) and 214(2) relate to the key switch functionality (e.g., open/closed) and are analogous to outwardly-facing electrical contacts 214(1)L and 214(1)R of FIG. 2A. When the key switch 118 is installed in through hole 114 in top portion 106, outwardly-facing electrical contact 214(1) can engage inwardly-facing electrical contact 202(1) on inwardly-facing minor surface 116, outwardly-facing electrical contact 214(2) can engage inwardly-facing electrical contact 202(2), outwardly-facing electrical contact 214(3) can engage inwardly-facing electrical contact 202(3), and outwardly-facing electrical contact 214(4) can engage inwardly-facing electrical contact 202(4).

FIG. 8 shows another example keyboard 104F that can employ a full color backlight solution. This configuration can support a full color LED 506 in the key switch 118. Toward this end, four conductors 702(1)-702(4) are connected to the receptacle 704 which receives four pins of the LED 506. The conductors 702 are in turn connected to outwardly-facing electrical contacts 214(1), 214(2), 214(5), and 214(6), respectively. As with the previous implementation shown in FIG. 7C, outwardly-facing electrical contacts 214(3) and 214(4) are dedicated to conveying key switch status (e.g., open/closed). As described above, the outwardly-facing electrical contacts 214 can be connected to traces 122 positioned on the top portion 106.

The present concepts include keyboards in which the top portion can mechanically support and electrically connect the key switches to other electronic components, such as processing units. These concepts can allow a fully customizable keyboard where the characteristics of individual key switches can be defined by the user. The user-defined key switches can be installed in the corresponding through holes where they are automatically mechanically supported and electronically connected. For instance, the user may want the keys under their index fingers, such as the “G” and “H” keys to have stiffer springs than keys that are engaged by their pinky fingers, such as the “A” key and the “″” (quotation mark) key. Other user-selectable key attributes can relate to audio levels produced by the key, key color, shape, label, etc. In some cases, the user (or designer) may specify key attributes on a user interface for individual key positions.

An assembler, either human or robotic can place the key switches having the desired properties in the corresponding through holes based upon the user-selected attributes. The key switches can be installed into the top portion with downward force where they are retained by the retention elements. The key switches are electronically and mechanically functional in the top portion without any underlying bottom portion and/or additional underlying electronic components.

Although techniques, methods, devices, systems, etc., pertaining to keyboards that employ top portions that mechanically and electronically support key switches are described in language specific to structural features and/or methodological acts, it is to be understood that the subject matter defined in the appended claims is not limited to the specific features or acts described. Rather, the specific features and acts are disclosed as example forms of implementing the claimed methods, devices, systems, etc.

Various examples are described above. Additional examples are described below. One example includes a keyboard comprising a top portion defining opposing first and second major surfaces and a through hole extending between the first and second major surfaces, the through hole defined by an inwardly-facing minor surface of the top portion and an inwardly-facing electrical contact positioned on the inwardly-facing minor surface and a key switch positioned at least partially in the through hole and having a user-engagement surface that is parallel to the first major surface and an outwardly-facing surface and an outwardly-facing electrical contact positioned on the outwardly-facing surface against the inwardly-facing electrical contact.

Another example can include any of the above and/or below examples where the key switch is configured where a downward movement of the user-engagement surface toward the second major surface completes an electrical circuit that includes the inwardly-facing electrical contact and the outwardly-facing electrical contact.

Another example can include any of the above and/or below examples where the keyboard further comprises a bottom portion underlying the top portion.

Another example can include any of the above and/or below examples where the key switch is suspended from the top portion and the bottom portion.

Another example can include any of the above and/or below examples where the bottom portion does not include or contact any electrical components.

Another example can include any of the above and/or below examples where the keyboard further comprises electrical traces positioned on the top portion.

Another example can include any of the above and/or below examples where the keyboard further comprises electrical traces extending from the key switch to a processing unit.

Another example can include any of the above and/or below examples where the processing unit comprises a printed circuit board positioned on the top portion but not underlying the key switch.

Another example can include any of the above and/or below examples where the processing unit is formed on the top portion.

Another example can include any of the above and/or below examples where the key switch comprises a self-contained electrical switch.

Another example can include any of the above and/or below examples where the inwardly-facing electrical contact comprises a first inwardly-facing electrical contact and a second inwardly-facing electrical contact and the outwardly-facing electrical contact comprises a first outwardly-facing electrical contact and a second outwardly-facing electrical contact.

Another example can include any of the above and/or below examples where the first inwardly-facing electrical contact and the first outwardly-facing electrical contact are electrically coupled to the self-contained electrical switch and the second inwardly-facing electrical contact and the second outwardly-facing electrical contact are electrically insulated from the self-contained electrical switch and are electrically coupled to another self-contained electrical switch.

Another example can include any of the above and/or below examples where the first inwardly-facing electrical contact and the first outwardly-facing electrical contact are electrically coupled to the self-contained electrical switch and the second inwardly-facing electrical contact and the second outwardly-facing electrical contact are electrically insulated from the self-contained electrical switch and are electrically coupled to a light associated with the self-contained electrical switch.

Another example includes a device comprising a top portion defining opposing first and second major surfaces and a through hole extending between the first and second major surfaces, the through hole defined by an inwardly-facing minor surface of the top portion and an inwardly-facing electrical contact positioned on the inwardly-facing minor surface, the top portion further including an electrical trace extending from the inwardly-facing electrical contact toward a processing unit and a self-contained key switch positioned at least partially in the through hole and having an outwardly-facing surface and an outwardly-facing electrical contact positioned on the outwardly-facing surface against the inwardly-facing electrical contact.

Another example can include any of the above and/or below examples where the self-contained key switch is not soldered to an underlying PCB or is not received in a socket of an underlying PCB.

Another example can include any of the above and/or below examples where the self-contained key switch is suspended from the top portion and does not physically or electrically contact any underlying components.

Another example can include any of the above and/or below examples where the self-contained key switch includes a retention element configured to provide a retention force to retain the self-contained key switch in the through hole.

Another example can include any of the above and/or below examples where the self-contained key switch comprises a user-engagement surface and movement of the user-engagement surface perpendicular to the first and second major surfaces closes the self-contained key switch and causes a circuit to be completed between the self-contained key switch and the processing unit.

Another example can include any of the above and/or below examples where the device comprises a keyboard that includes a bottom cover that does not include any electronic components but that physically supports the top cover when forces are applied to the top cover perpendicular to the first and second major surfaces or wherein the device comprises a vehicle and wherein the top cover is positioned on a control area comprising a dash or cockpit.

Another example includes a keyboard comprising a top portion and an opposing bottom portion, key switches that are mechanically retained in holes formed in the top cover, and electrical traces formed on the top cover that extend from the holes to a processing unit that is configured to receive electrical signals along the electrical traces when the key switches are closed.

1. A keyboard (104), comprising:
a top portion (106) defining opposing first and second major surfaces (110, 112) and a through hole (114) extending between the first and second major surfaces, the through hole defined by an inwardly-facing minor surface (116) of the top portion and an inwardly-facing electrical contact (202) positioned on the inwardly-facing minor surface; and,
a key switch (118) positioned at least partially in the through hole and having a user-engagement surface (216) that is generally parallel to the first major surface and an outwardly-facing surface (120) and an outwardly-facing electrical contact (214) positioned on the outwardly-facing surface against the inwardly-facing electrical contact.

2. The keyboard of claim 1, wherein the key switch is configured where a downward movement of the user-engagement surface toward the second major surface completes an electrical circuit that includes the inwardly-facing electrical contact and the outwardly-facing electrical contact.

3. The keyboard of claim 1, further comprising a bottom portion underlying the top portion.

4. The keyboard of claim 3, wherein the key switch is suspended from the top portion and does not contact the bottom portion.

5. The keyboard of claim 4, wherein the bottom portion does not include or contact any electrical components.

6. The keyboard of claim 4, further comprising electrical traces positioned on the top portion.

7. The keyboard of claim 4, further comprising electrical traces extending from the key switch to a processing unit.

8. The keyboard of claim 7, wherein the processing unit comprises a printed circuit board positioned on the top portion but not underlying the key switch.

9. The keyboard of claim 7, wherein the processing unit is formed on the top portion.

10. The keyboard of claim 1, wherein the key switch comprises a self-contained electrical switch.

11. The keyboard of claim 10, wherein the inwardly-facing electrical contact comprises a first inwardly-facing electrical contact and a second inwardly-facing electrical contact and the outwardly-facing electrical contact comprises a first outwardly-facing electrical contact and a second outwardly-facing electrical contact.

12. The keyboard of claim 11, wherein the first inwardly-facing electrical contact and the first outwardly-facing electrical contact are electrically coupled to the self-contained electrical switch and the second inwardly-facing electrical contact and the second outwardly-facing electrical contact are electrically insulated from the self-contained electrical switch and are electrically coupled to another self-contained electrical switch.

13. The keyboard of claim 11, wherein the first inwardly-facing electrical contact and the first outwardly-facing electrical contact are electrically coupled to the self-contained electrical switch and the second inwardly-facing electrical contact and the second outwardly-facing electrical contact are electrically insulated from the self-contained electrical switch and are electrically coupled to a light associated with the self-contained electrical switch.

14. A device (102), comprising:
a top portion (106) defining opposing first and second major surfaces (110, 112) and a through hole (114) extending between the first and second major surfaces, the through hole defined by an inwardly-facing minor surface (116) of the top portion and an inwardly-facing electrical contact (202) positioned on the inwardly-facing minor surface, the top portion further including an electrical trace (122) extending from the inwardly-facing electrical contact toward a processing unit (126); and,
a self-contained key switch (118) positioned at least partially in the through hole and having an outwardly-facing surface (120) and an outwardly-facing electrical contact (214) positioned on the outwardly-facing surface against the inwardly-facing electrical contact.

15. The device of claim 14, wherein the self-contained key switch is not soldered to an underlying PCB or is not received in a socket of an underlying PCB.

16. The device of claim 14, wherein the self-contained key switch is suspended from the top portion and does not physically or electrically contact any underlying components.

17. The device of claim 14, wherein the self-contained key switch includes a retention element (210) configured to provide a retention force to retain the self-contained key switch in the through hole.

18. The device of claim 14, wherein the self-contained key switch comprises a user-engagement surface and movement of the user-engagement surface perpendicular to the first and second major surfaces closes the self-contained key switch and causes a circuit to be completed between the self-contained key switch and the processing unit.

19. The device of claim 14, wherein the device comprises a keyboard that includes a bottom cover that does not include any electronic components but that physically supports the top portion when forces are applied to the top portion perpendicular to the first and second major surfaces or wherein the device comprises a vehicle and wherein the top portion is positioned on a control area comprising a dash or cockpit.

20. A keyboard (104), comprising:
a top portion (106) and an opposing bottom portion (108);
key switches (118) that are mechanically retained in holes (114) formed in the top portion; and,
electrical traces (122) formed on the top portion that extend from the holes to a processing unit (126) that is configured to receive electrical signals along the electrical traces when the key switches are closed.
